(19) United States
(12) Patent Application Publication
(10) Pub. No.: US 2025/0176185 A1
(43) Pub. Date: May 29, 2025

(54) SONOS STRUCTURE, METHOD FOR PROGRAMMING THE SAME AND METHOD FOR FORMING THE SAME, AND MEMORY

(71) Applicant: SHANGHAI HUAHONG GRACE SEMICONDUCTOR MANUFACTURING CORPORATION, Shanghai (CN)

(72) Inventors: Yang DING, Shanghai (CN); Kegang ZHANG, Shanghai (CN)

(73) Assignee: SHANGHAI HUAHONG GRACE SEMICONDUCTOR MANUFACTURING CORPORATION, Shanghai (CN)

(21) Appl. No.: 18/853,580

(22) PCT Filed: Jul. 21, 2023
(86) PCT No.: PCT/CN2023/108519

§ 371 Date: Oct. 2, 2024

(30) Foreign Application Priority Data
Nov. 3, 2022 (CN) 202211372002.4

(51) Int. Cl. H10B 43/30; G11C 16/04; G11C 16/10; G11C 16/14; G11C 16/26

(52) U.S. Cl. CPC H10B 43/30; G11C 16/0466; G11C 16/10; G11C 16/14; G11C 16/26

(57) ABSTRACT

A SONOS structure, a method for erasing the SONOS structure, and a method for programming the SONOS structure are provided. The SONOS structure includes a semiconductor substrate, a dielectric layer disposed on the semiconductor substrate, a charge trapping layer disposed on the dielectric layer, a tunneling dielectric layer covering the charge trapping layer, and a conductive layer disposed on the tunneling dielectric layer. A thickness of the dielectric layer is greater than a thickness of the tunneling dielectric layer.

### CROSS-REFERENCE TO RELATED APPLICATIONS

This application claims the priority to Chinese Application No. 202211372002.4, filed on Nov. 3, 2022, and entitled “SONOS STRUCTURE, PROGRAMMING METHOD AND FORMING METHOD THEREFOR, AND MEMORY”, the contents of which are incorporated herein by reference in their entirety.

### TECHNICAL FIELD

The present disclosure generally relates to semiconductor technology field, and more particularly, to a Silicon Oxide Nitride Oxide Semiconductor (SONOS) structure, a method for programming the SONOS structure, a method for forming the SONOS structure, and a memory.

### BACKGROUND

Currently, a semiconductor memory for data storage may include a volatile memory and a non-volatile memory. The volatile memory is prone to losing data when a power supply is interrupted. The non-volatile memory can retain data even when a power supply is interrupted, and is widely used in mobile communication systems or memory cards.

In the existing technology, a non-volatile memory cell may be implemented as an SONOS structure. In an SONOS memory, carriers can be injected into a silicon nitride layer through a tunneling oxide layer based on a Channel Hot Electron Injection (CHE) effect or an FN tunneling effect, and can be trapped by charge traps in the silicon nitride layer, which causes a change of a threshold voltage of a device cell and achieves data storage.

However, an existing SONOS memory is highly dependent on the tunneling oxide layer disposed on a substrate channel, and defects in the tunneling oxide layer caused by channel hot carriers injection may easily cause storage failure.

### SUMMARY

Embodiments of the present disclosure provide an SONOS structure, a method for programming the SONOS structure, a method for forming the SONOS structure, and a memory, which can effectively improve storage reliability.

According to embodiments of the present disclosure, an SONOS structure is provided. The SONOS structure includes: a semiconductor substrate; a dielectric layer disposed on the semiconductor substrate; a charge trapping layer disposed on the dielectric layer; a tunneling dielectric layer covering the charge trapping layer; and a conductive layer disposed on the tunneling dielectric layer. A thickness of the dielectric layer is greater than a thickness of the tunneling dielectric layer.

According to embodiments, the SONOS structure further includes a gradient oxynitride layer disposed on the charge trapping layer, and the tunneling dielectric layer is disposed on the gradient oxynitride layer.

According to embodiments, the charge trapping layer is made of a nitride. In the gradient oxynitride layer, the closer to the charge trapping layer, the higher a nitrogen content is.

According to embodiments, the tunneling dielectric layer is made of an oxide. In the gradient oxynitride layer, the closer to the tunneling dielectric layer, the higher an oxygen content is.

According to embodiments, the dielectric layer is made of an oxide, the charge trapping layer is made of a nitride, the tunneling dielectric layer is made of an oxide, and/or the conductive layer is made of a polycrystalline silicon.

According to embodiments of the present disclosure, a method for erasing the SONOS structure is provided. The SONOS structure further includes a source and a drain disposed in the semiconductor substrate. The method for erasing the SONOS structure includes: applying a negative erasing voltage to the conductive layer, and grounding the drain.

According to embodiments of the present disclosure, a method for programming the SONOS structure is provided. The SONOS structure further includes a source and a drain disposed in the semiconductor substrate. The method for programming the SONOS structure includes: applying a positive programming voltage to the conductive layer, and applying a positive programming voltage to the drain or grounding the drain. The positive programming voltage applied to the conductive layer is greater than the positive programming voltage applied to the drain.

According to embodiments, the method further includes: when programming “1”, the positive programming voltage being applied to the drain; and/or when programming “0”, the drain being grounded.

According to embodiments of the present disclosure, a method for reading the SONOS structure is provided. The SONOS structure further includes a source and a drain disposed in the semiconductor substrate. The method for reading the SONOS structure includes: grounding the conductive layer and applying a positive reading voltage to the drain.

According to embodiments of the present disclosure, a method for forming an SONOS structure is provided. The method includes: providing a semiconductor substrate; forming a dielectric layer on the semiconductor substrate; forming a charge trapping layer on the dielectric layer; forming a tunneling dielectric layer covering the charge trapping layer; and forming a conductive layer on the tunneling dielectric layer. A thickness of the dielectric layer is greater than a thickness of the tunneling dielectric layer.

According to embodiments, the method further includes: forming a gradient oxynitride layer on the charge trapping layer before forming the tunneling dielectric layer. The tunneling dielectric layer is disposed on the gradient oxynitride layer.

According to embodiments, the charge trapping layer is made of a nitride. The gradient oxynitride layer is formed on the charge trapping layer through an oxidation process in a process environment containing nitrogen and oxygen. In the gradient oxynitride layer, the closer to the charge trapping layer, the higher a nitrogen content is.

According to embodiments of the present disclosure, a memory including the aforementioned SONOS structure is provided.

Compared with existing technology, embodiments of the present disclosure may have following advantages.

According to some embodiments of the present disclosure, a thick dielectric layer is formed on the semiconductor substrate, and then a charge trapping layer, a thin tunneling dielectric layer, and a conductive layer are sequentially formed. In subsequent reading, writing and erasing operations, under a positive/negative voltage applied to the conductive layer, carriers from the conductive layer can tunnel through the tunneling dielectric layer and be stored in the charge trapping layer. According to the existing technology, a tunneling dielectric layer is disposed on a semiconductor substrate and carriers from the substrate channel can pass through the tunneling dielectric layer, and defects in the tunneling oxide layer easily caused by channel hot carriers injection may cause storage failure. According to embodiments of the present disclosure, a flow path of carriers is far away from the substrate channel, and an ability to resist hot carriers crosstalk can thus be greatly enhanced. Specifically, the dielectric layer disposed on the substrate channel is relatively thick, which has a blocking effect of reducing a possibility of hot carriers in the substrate channel being injected into the charge trapping layer, thereby effectively reducing hot carriers crosstalk and improving storage reliability.

Further, according to some embodiments of the present disclosure, the SONOS structure further includes a gradient oxynitride layer. The gradient oxynitride layer may be formed on the charge trapping layer through an oxidation process in a process environment containing nitrogen and oxygen, such that covalent bonds between nitrogen, oxygen and an element (e.g., silicon or germanium) included in the semiconductor substrate may be formed in the gradient oxynitride layer. The closer to the charge trapping layer, the higher the nitrogen content is (e.g., more covalent bonds are Si—N bonds). The farther away from the charge trapping layer, the lower the nitrogen content is, and correspondingly, the higher the oxygen content is (e.g., more covalent bonds are Si—O bonds). Therefore, a gradient energy band is formed, which reduces a potential barrier for carriers injecting into the charge trapping layer.

Further, according to some embodiments of the present disclosure, in the method for erasing the SONOS structure, a negative erasing voltage can be applied to the conductive layer, and the drain can be grounded. In a specific application of the existing technology, although the tunneling dielectric layer is disposed on the semiconductor substrate and carriers from the substrate channel can pass through the tunneling dielectric layer, a negative erasing voltage can be applied to a gate and a drain can be grounded in an erasing operation. Therefore, the method of applying voltage in the existing erasing operation can be utilized in some embodiments of the present disclosure, thereby improving an adaptability to the existing technology, and reducing a difficulty of process adjustment and a complexity of research and development.

Further, according to some embodiments of the present disclosure, in the method for programming the SONOS structure, a relatively high positive programming voltage may be applied to the conductive layer, and a relatively low positive programming voltage may be applied to the drain or the drain may be grounded. In a specific application of the existing technology, although the tunneling dielectric layer is disposed on the semiconductor substrate and carriers from the substrate channel can pass through the tunneling dielectric layer, a relatively high positive programming voltage can be applied to the gate, and a relatively low positive programming voltage can be applied to the drain or the drain can be grounded in a programming operation. Therefore, the method of applying voltage in the existing programming operation can be utilized in some embodiments of the present disclosure, thereby improving an adaptability to the existing technology, and reducing a difficulty of process adjustment and a complexity of research and development.

Further, according to some embodiments of the present disclosure, in the method for reading the SONOS structure, the conductive layer may be grounded and a positive reading voltage may be applied to the drain. In a specific application of the existing technology, although the tunneling dielectric layer is disposed on the semiconductor substrate and carriers from the substrate channel can pass through the tunneling dielectric layer, the gate can be grounded and a positive reading voltage can be applied to the drain in a reading operation. Therefore, the method of applying voltage in the existing reading operation can be utilized in some embodiments of the present disclosure, thereby improving an adaptability to the existing technology, and reducing a difficulty of process adjustment and a complexity of research and development.

### BRIEF DESCRIPTION OF THE DRAWINGS

FIG. 1 schematically illustrates a cross-sectional structural diagram of an SONOS structure according to existing technology;

FIG. 2 schematically illustrates a cross-sectional structural diagram of an SONOS structure according to some embodiments of present disclosure;

FIG. 3 schematically illustrates a diagram of a working scenario of an erasing operation based on an SONOS structure according to some embodiments of present disclosure;

FIG. 4 schematically illustrates a diagram of a working scenario of a programming “1” operation based on an SONOS structure according to some embodiments of present disclosure;

FIG. 5 schematically illustrates a diagram of a working scenario of a programming “0” operation based on an SONOS structure according to some embodiments of present disclosure;

FIG. 6 schematically illustrates a diagram of a working scenario of a reading operation based on an SONOS structure according to some embodiments of present disclosure; and

FIG. 7 schematically illustrates a flowchart of a method for forming an SONOS structure according to some embodiments of present disclosure.

### REFERENCE NUMERALS

semiconductor substrate 100, source 101, drain 102, gate stack structure 110, tunneling dielectric layer 111, charge trapping layer 112, top dielectric layer 113, conductive layer 114, semiconductor substrate 200, source 201, drain 202, gate stack structure 210, tunneling dielectric layer 211, charge trapping layer 212, dielectric layer 213, conductive layer 214, and gradient oxynitride layer 215.

### DETAILED DESCRIPTION

In an existing SONOS memory, carriers can be injected into a silicon nitride layer through a tunneling oxide layer based on a channel hot electron injection effect or an FN tunneling effect, and can be trapped by charge traps in the silicon nitride layer, which causes a change of a threshold voltage of a device cell and achieves data storage.

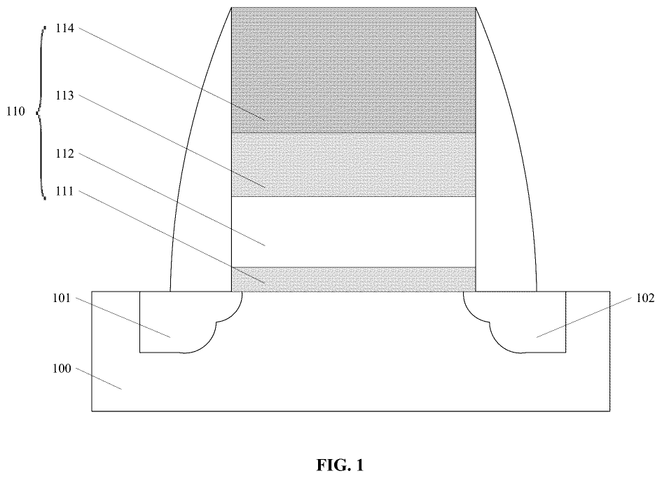

FIG. 1 schematically illustrates a cross-sectional structural diagram of an SONOS structure according to existing technology. Referring to FIG. 1, the SONOS structure may include: a semiconductor substrate 100, a gate stack structure 110 disposed on the semiconductor substrate 100, and a source 101 and a drain 102 which are disposed in the semiconductor substrate 100 and disposed on both sides of the gate stack structure 110.

According to some embodiments, the gate stack structure 110 may include: a tunneling dielectric layer 111, a charge trapping layer 112, a top dielectric layer 113 and a conductive layer 114.

According to some embodiments, the tunneling dielectric layer 111 may be made of silicon oxide, the charge trapping layer 112 may be made of silicon nitride, and the top dielectric layer 113 may be made of silicon oxide. Therefore, the tunneling dielectric layer 11, the charge trapping layer 12 and the top dielectric layer 13 form an Oxide-Nitride-Oxide (ONO) structure, and the conductive layer 114 may be made of a metal material.

Specifically, taking the SONOS structure shown in FIG. 1 as an N-type device, an operation principle of the SONOS structure is described as follows. During a programming operation, a positive programming voltage is applied to the gate stack structure 110, and at the same time, electrons in the substrate channel pass through the tunneling dielectric layer 111 based on the channel hot electron injection effect or the FN tunneling effect, and are stored in the charge trapping layer 112, thereby completing the programming operation. During an erasing operation, a negative voltage is applied to the gate stack structure 110, and electrons in the charge trapping layer 12 tunnel into the semiconductor substrate 100 through the tunneling dielectric layer 111 at the same time, thereby completing the erasing operation.

In the existing technology, the tunneling dielectric layer 111 is disposed on the semiconductor substrate 100, and carriers from the substrate channel can pass through the tunneling dielectric layer 111, and defects in the tunneling dielectric layer 111 easily caused by channel hot carriers injection may cause storage failure.

According to some embodiments of the present disclosure, a thick dielectric layer is formed on the semiconductor substrate, and then a charge trapping layer, a thin tunneling dielectric layer, and a conductive layer are sequentially formed. In subsequent reading, writing and erasing operations, under a positive/negative voltage applied to the conductive layer, carriers from the conductive layer can tunnel through the tunneling dielectric layer and be stored in the charge trapping layer. According to the existing technology, a tunneling dielectric layer is disposed on a semiconductor substrate and carriers from the substrate channel can pass through the tunneling dielectric layer, and defects in the tunneling oxide layer easily caused by channel hot carriers injection may cause storage failure. According to embodiments of the present disclosure, a flow path of carriers is far away from the substrate channel, and an ability to resist hot carriers crosstalk can thus be greatly enhanced. Specifically, the dielectric layer disposed on the substrate channel is relatively thick, which has a blocking effect of reducing a possibility of hot carriers in the substrate channel being injected into the charge trapping layer, thereby effectively reducing hot carriers crosstalk and improving storage reliability.

In order to clarify the object, features and advantages of the present disclosure, embodiments of present disclosure will be described in detail in conjunction with accompanying figures.

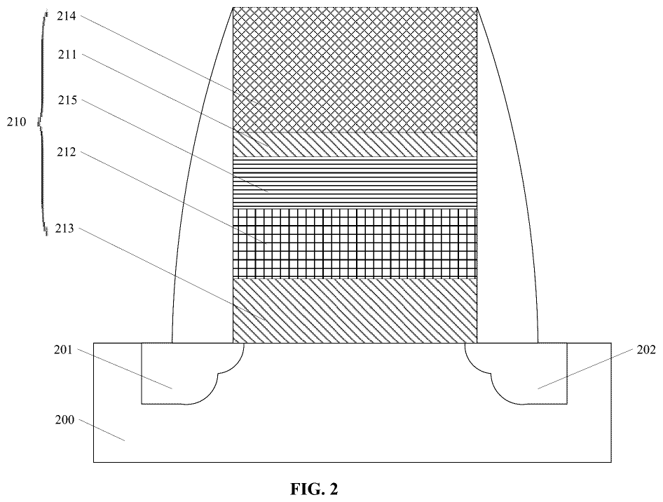

Referring to FIG. 2, FIG. 2 schematically illustrates a cross-sectional structural diagram of an SONOS structure according to some embodiments of present disclosure.

The SONOS structure may include a semiconductor substrate 200 and a gate stack structure 210.

According to some embodiments, the gate stack structure 210 may include: a dielectric layer 213, a charge trapping layer 212, a tunneling dielectric layer 211 and a conductive layer 214. The gate stack structure 210 may further include a gradient oxynitride layer 215.

According to some embodiments, the dielectric layer 213 may be disposed on the semiconductor substrate 200, the charge trapping layer 212 may be disposed on the dielectric layer 213 and covered by the tunneling dielectric layer 211, and the conductive layer 214 may be disposed on the tunneling dielectric layer 211.

It should be noted that, compared with the existing technology illustrated in FIG. 1, the dielectric layer 213, the charge trapping layer 212 and the tunneling dielectric layer 211 in the embodiments of the present disclosure illustrated in FIG. 2 are formed in a different sequence and disposed at different positions.

According to some embodiments, a thickness of the dielectric layer 213 is greater than a thickness of the tunneling dielectric layer 211.

Further, the thickness of the dielectric layer 213 may be greater than or equal to a predetermined multiple N of the thickness of the tunneling dielectric layer 211, and N is a rational number and N is greater than a predetermined value.

As a non-limiting example, N may be 2 or 3. In other words, the thickness of the dielectric layer 213 may be greater than two to three times the thickness of the tunneling dielectric layer 211. If the thickness of the tunneling dielectric layer 211 ranges from 1 nm to 2 nm, the thickness of the dielectric layer 213 may range from 4 nm to 5 nm.

According to some embodiments, the dielectric layer 213 having a relatively thick thickness provides protection and isolation for carriers in the substrate channel, and the tunneling dielectric layer 211 having a relatively thin thickness enables carriers in the conductive layer 214 to pass through the tunneling dielectric layer 211.

According to some embodiments, the semiconductor substrate 200 may be a silicon substrate, and may also be made of a suitable material including germanium, silicon germanide, silicon carbide, gallium arsenide, and indium gallium. The semiconductor substrate 200 may also be a silicon substrate disposed on an insulator surface or a germanium substrate disposed on an insulator surface, or a substrate with an epitaxy layer (or an epi layer) grown thereon. According to some non-limiting embodiments, the semiconductor substrate 200 may be lightly doped, and a doping type is opposite to a doping type of the drain. Specifically, a deep well implant can be achieved through ion implantation into the semiconductor substrate 200.

Further, the dielectric layer 213 may be made of an oxide, the charge trapping layer 212 may be made of a nitride, the tunneling dielectric layer 211 may be made of an oxide, and the conductive layer 214 may be made of a polycrystalline silicon.

Specifically, a material of each layer of the gate stack structure 210 may be determined based on the semiconductor substrate 200 made of a silicon substrate or a germanium substrate.

For example, the semiconductor substrate 200 is a silicon substrate, the dielectric layer 213 is made of silicon oxide, the charge trapping layer 212 is made of silicon nitride, and the tunneling dielectric layer 211 is made of silicon oxide.

Further, for example, the thickness of the tunneling dielectric layer 211 ranges from 1 nm to 2 nm and the thickness of the dielectric layer 213 ranges from 4 nm to 5 nm, thus a thickness of the charge trapping layer 212 may range from 6 nm to 7 nm, and a thickness of the conductive layer 214 may range from 200 nm to 250 nm.

According to some embodiments of the present disclosure, a thick dielectric layer 213 is formed on the semiconductor substrate 200, and then a charge trapping layer 212, a thin tunneling dielectric layer 211, and a conductive layer 214 are sequentially formed. In subsequent reading, writing and erasing operations, under a positive/negative voltage applied to the conductive layer 214, carriers from the conductive layer 214 can tunnel through the tunneling dielectric layer 211 and be stored in the charge trapping layer 212. According to the existing technology, a tunneling dielectric layer is disposed on a semiconductor substrate and carriers from the substrate channel can pass through the tunneling dielectric layer, and defects in the tunneling oxide layer easily caused by channel hot carriers injection may cause storage failure. According to embodiments of the present disclosure, a flow path of carriers is far away from the substrate channel, and an ability to resist hot carriers crosstalk can thus be greatly enhanced. Specifically, the dielectric layer 213 disposed on the substrate channel is relatively thick, which has a blocking effect of reducing a possibility of hot carriers in the substrate channel being injected into the charge trapping layer 212, thereby effectively reducing hot carriers crosstalk and improving storage reliability.

Further, the SONOS structure further includes a gradient oxynitride layer 215 disposed on the charge trapping layer 212, and the tunneling dielectric layer 211 is disposed on the gradient oxynitride layer 215.

According to some embodiments of the present disclosure, a gradient material layer including nitrogen and oxygen provides a gradient from higher nitrogen content to higher oxygen content, thereby reducing a potential barrier for carriers injecting into the charge trapping layer 212. Carriers from the conductive layer 214 can tunnel through the tunneling dielectric layer 211, and then pass through the gradient oxynitride layer 215 and are finally stored in the charge trapping layer 212.

Further, the charge trapping layer 212 may be made of a nitride. In the gradient oxynitride layer 215, the closer to the charge trapping layer 212, the higher the nitrogen content is.

Further, the tunneling dielectric layer 211 may be made of an oxide. In the gradient oxynitride layer 215, the closer to the tunneling dielectric layer 211, the higher the oxygen content is.

It should be noted that, if the charge trapping layer 212 or the tunneling dielectric layer 211 is made of a material including another element that is capable of forming covalent bonds, in the gradient oxynitride layer 215, the closer to the charge trapping layer 212 or the tunneling dielectric layer 211, the higher the content of the corresponding element is.

According to a non-limiting embodiment, the charge trapping layer 212 may be made of a nitride, and the gradient oxynitride layer 215 may be formed on the charge trapping layer 212 through an oxidation process in a process environment containing nitrogen and oxygen. In the gradient oxynitride layer 215, the closer to the charge trapping layer 212, the higher the nitrogen content is.

According to some embodiments, covalent bonds between nitrogen, oxygen, and an element (e.g., silicon or germanium) included in a semiconductor substrate may be formed in the gradient oxynitride layer 215. The closer to the charge trapping layer 212, the higher the nitrogen content is (e.g., more covalent bonds are Si—N bonds). The farther away from the charge trapping layer 212, the lower the nitrogen content is, and correspondingly, the higher the oxygen content is (e.g., more covalent bonds are Si—O bonds). A gradient from more nitrogen to more oxygen reduces a potential barrier for carriers injecting into the charge trapping layer 212. Carriers from the conductive layer 214 can tunnel through the tunneling dielectric layer 211, and then pass through the gradient oxynitride layer 215 and are finally stored in the charge trapping layer 212.

Further, for example, the thickness of the tunneling dielectric layer 211 ranges from 1 nm to 2 nm and the thickness of the dielectric layer 213 ranges from 4 nm to 5 nm, thus a thickness of the gradient oxynitride layer 215 may range from 3 nm to 5 nm.

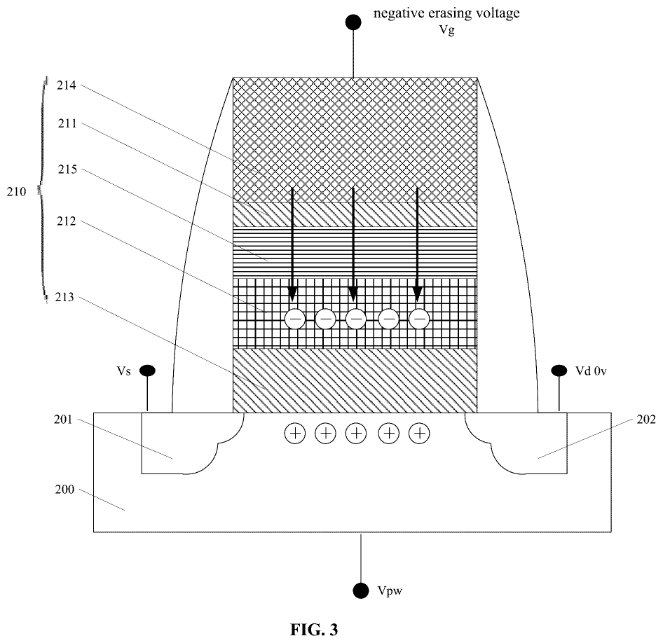

According to some embodiments of the present disclosure, reading, writing and erasing operations for the SONOS structure are described below in conjunction with FIGS. 3 to 5. Vg represents a voltage applied to the gate stack structure 210, Vs represents a voltage applied to a source 201, Vd represents a voltage applied to a drain 202, and Vpw represents a voltage applied to the semiconductor substrate 200.

It is noted that in the following embodiments, unless otherwise stated, taking an N-type device as an example for illustration. The source 201 and the drain 202 are doped with N-type ions, the semiconductor substrate 200 is P-well doped, and carriers are mainly composed of electrons.

Further, the SONOS structure may further include the source 201 and the drain 202 which are disposed in the semiconductor substrate 200. A method for erasing the SONOS structure includes: applying a negative erasing voltage to the conductive layer 214 and grounding the drain 202.

Referring to FIG. 3, FIG. 3 schematically illustrates a diagram of a working scenario of an erasing operation based on an SONOS structure according to some embodiments of present disclosure.

Specifically, according to some embodiments of the present disclosure, an operating principle of the erasing operation for the SONOS structure may include: a negative erasing voltage is applied to the conductive layer 214 and the drain 202 is grounded, and negative carriers in the conductive layer 214 pass into the charge trapping layer 212 through the tunneling dielectric layer 211, thereby completing the erasing operation.

According to a non-limiting embodiment, a voltage ranging from −13V to −10V is applied to the gate stack structure 210, the drain 202 and the semiconductor substrate 200 are grounded (i.e., 0V is applied), and the source 201 is floated. Therefore, electrons in the conductive layer 214 can be injected into the charge trapping layer 212 that serves as a storage medium, and can be stored in the charge trapping layer 212.

After the erasing operation, a surface channel of the semiconductor substrate 200 may be in an “off” state which is “1”.

According to some embodiments, in the erasing method, a negative erasing voltage can be applied to the conductive layer 214, and the drain 202 can be grounded. According to a specific application of the existing technology, although a tunneling dielectric layer is disposed on a semiconductor substrate and carriers from the substrate channel can pass through the tunneling dielectric layer, a negative erasing voltage can be applied to a gate and a drain can be grounded in an erasing operation. Therefore, the method of applying voltage in the existing erasing operation can be utilized in some embodiments of the present disclosure, thereby improving an adaptability to the existing technology, and reducing a difficulty of process adjustment and a complexity of research and development.

Further, the SONOS structure may further include the source 201 and the drain 202 which are disposed in the semiconductor substrate 200. A method for programming the SONOS structure includes: applying a positive programming voltage to the conductive layer 214, and applying a positive programming voltage to the drain 202 or grounding the drain 202. The positive programming voltage applied to the conductive layer 214 is greater than the positive programming voltage applied to the drain 202.

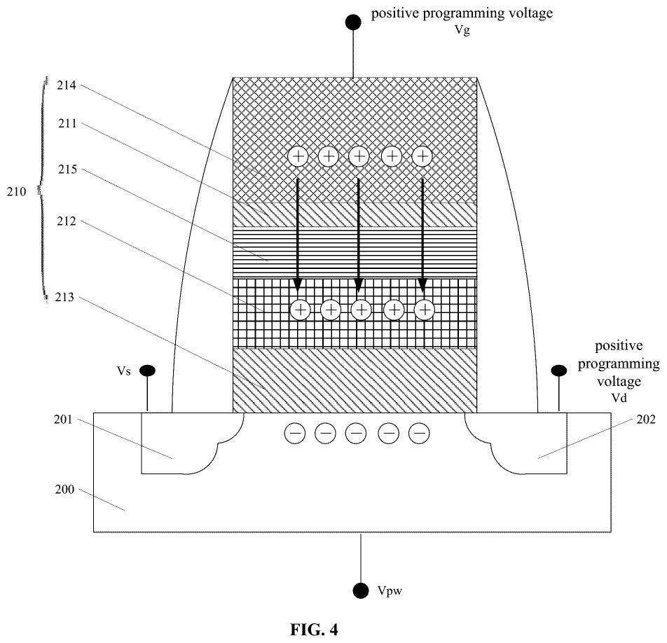

Referring to FIG. 4, FIG. 4 schematically illustrates a diagram of a working scenario of a programming “1” operation based on an SONOS structure according to some embodiments of present disclosure.

Specifically, according to some embodiments of the present disclosure, an operating principle of the programming “1” operation for the SONOS structure may include: a positive programming voltage is applied to the gate stack structure 210 and a positive programming voltage is applied to the drain 202, and positive carriers in the conductive layer 214 pass through the tunneling dielectric layer 211 and are stored in the charge trapping layer 212, thereby completing the programming “1” operation.

According to a non-limiting embodiment, a voltage ranging from 10V to 13V is applied to the gate stack structure 210, the semiconductor substrate 200 is grounded (i.e., 0V is applied), a voltage ranging from 5V to 7V is applied to the drain 202, and the source 201 is floated. Therefore, holes in the conductive layer 214 can be injected into the charge trapping layer 212 that serves as a storage medium, and can be stored in the charge trapping layer 212.

After the programming “1” operation, a storing charge state changes and the surface channel of the semiconductor substrate 200 may be in the “off” state.

According to some embodiments, in the programming “1” method, a relatively high positive programming voltage may be applied to the conductive layer, and a relatively low positive programming voltage may be applied to the drain. In a specific application of the existing technology, although the tunneling dielectric layer is disposed on the semiconductor substrate and carriers from the substrate channel can pass through the tunneling dielectric layer, a relatively high positive programming voltage can be applied to the gate and a relatively low positive programming voltage can be applied to the drain in a programming operation. Therefore, the method of applying voltage in the existing programming operation can be utilized in some embodiments of the present disclosure, thereby improving an adaptability to the existing technology, and reducing a difficulty of process adjustment and a complexity of research and development.

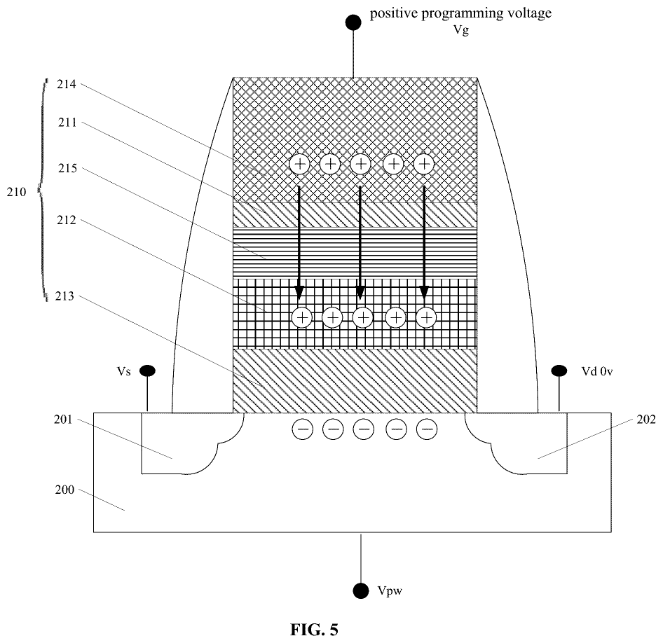

Referring to FIG. 5, FIG. 5 schematically illustrates a diagram of a working scenario of a programming “0” operation based on an SONOS structure according to some embodiments of present disclosure.

Specifically, according to some embodiments of the present disclosure, an operating principle of the programming “0” operation for the SONOS structure may include: a positive programming voltage is applied to the gate stack structure 210 and the drain 202 is grounded (i.e., 0V is applied), and positive carriers in the conductive layer 214 pass through the tunneling dielectric layer 211 and are stored in the charge trapping layer 212, thereby completing the programming “0” operation.

According to a non-limiting embodiment, a voltage ranging from 10V to 13V is applied to the gate stack structure 210, the semiconductor substrate 200 is grounded (i.e., 0V is applied), the drain 202 is grounded (i.e., 0V is applied), and the source 201 is floated. Therefore, holes in the conductive layer 214 can be injected into the charge trapping layer 212 that serves as a storage medium, and can be stored in the charge trapping layer 212.

After the programming “0” operation, the storing charge state changes and the surface channel of the semiconductor substrate 200 may be in an “on” state.

According to some embodiments, in the programming “0” method, a relatively high positive programming voltage may be applied to the conductive layer 214, and the drain 202 is grounded (i.e., 0V is applied). In a specific application of the existing technology, although the tunneling dielectric layer is disposed on the semiconductor substrate and carriers from the substrate channel can pass through the tunneling dielectric layer, a relatively high positive programming voltage can be applied to the gate and a relatively low positive programming voltage can be applied to the drain in a programming operation. Therefore, the method of applying voltage in the existing programming operation can be utilized in some embodiments of the present disclosure, thereby improving an adaptability to the existing technology, and reducing a difficulty of process adjustment and a complexity of research and development.

Further, the SONOS structure may further include the source 201 and the drain 202 which are disposed in the semiconductor substrate 200. The method for reading the SONOS structure includes: grounding the conductive layer 214, and applying a positive reading voltage to the drain 202.

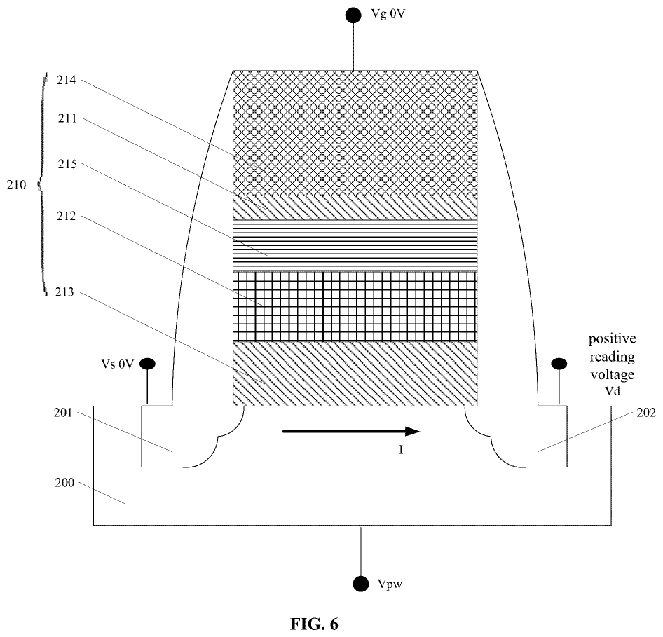

Referring to FIG. 6, FIG. 6 schematically illustrates a diagram of a working scenario of a reading operation based on an SONOS structure according to some embodiments of present disclosure.

Specifically, according to some embodiments of the present disclosure, an operating principle of the reading operation for the SONOS structure may include: the conductive layer 214 is grounded, a positive reading voltage is applied to the drain 202, and there is no voltage difference between Vg and Vpw. Therefore, carriers in the gate stack structure 210 may not flow, and carriers in the substrate channel are affected by Vd and can thus generate a current from the source 201 to the drain 202.

According to a non-limiting embodiment, the gate stack structure 210, the source 201, and the semiconductor substrate 200 may be grounded (i.e., 0V is applied), and a positive reading voltage may be applied to the drain 202.

Further, the positive reading voltage applied to the drain 202 ranges from 0.5 V to 2 V, e.g., 1 V.

According to some embodiments, in the reading method, the conductive layer 214 may be grounded and a relatively low positive reading voltage may be applied to the drain 202. In a specific application of the existing technology, although the tunneling dielectric layer is disposed on the semiconductor substrate and carriers from the substrate channel can pass through the tunneling dielectric layer, the gate can be grounded and a positive reading voltage can be applied to the drain in a reading operation. Therefore, the method of applying voltage in the existing reading operation can be utilized in some embodiments of the present disclosure, thereby improving an adaptability to the existing technology, and reducing a difficulty of process adjustment and a complexity of research and development.

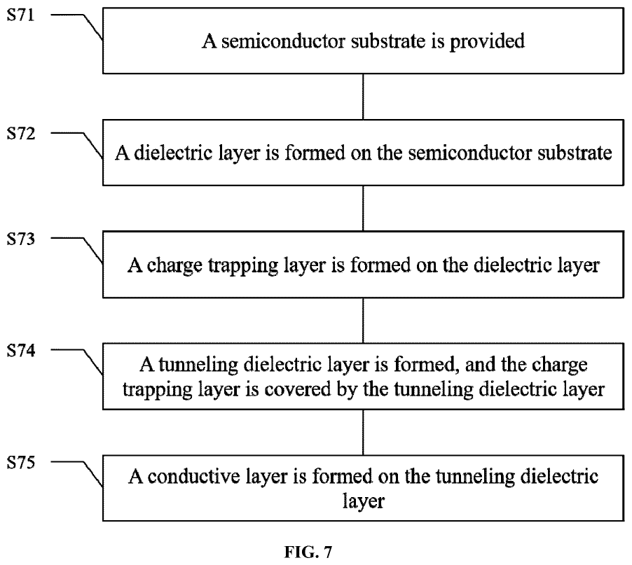

FIG. 7 schematically illustrates a flowchart of a method for forming an SONOS structure according to some embodiments of present disclosure. Referring to FIG. 7, the method for forming the SONOS structure may include steps S71 to S75.

S71: a semiconductor substrate is provided.

S72: a dielectric layer is formed on the semiconductor substrate.

S73: a charge trapping layer is formed on the dielectric layer.

S74: a tunneling dielectric layer is formed, and the charge trapping layer is covered by the tunneling dielectric layer.

S75: a conductive layer is formed on the tunneling dielectric layer.

A thickness of the dielectric layer is greater than a thickness of the tunneling dielectric layer.

According to some embodiments of the present disclosure, a thick dielectric layer is formed on the semiconductor substrate, and then a charge trapping layer, a thin tunneling dielectric layer, and a conductive layer are sequentially formed. In subsequent reading, writing and erasing operations, under a positive/negative voltage applied to the conductive layer, carriers from the conductive layer can tunnel through the tunneling dielectric layer and be stored in the charge trapping layer. According to the existing technology, a tunneling dielectric layer is disposed on a semiconductor substrate and carriers from the substrate channel can pass through the tunneling dielectric layer, and defects in the tunneling oxide layer easily caused by channel hot carriers injection may cause storage failure. According to embodiments of the present disclosure, the dielectric layer disposed on the substrate channel is relatively thick, which has a blocking effect of reducing a possibility of hot carriers in the substrate channel being injected into the charge trapping layer, thereby effectively reducing hot carriers crosstalk and improving storage reliability.

According to some embodiments, the method further includes: forming a gradient oxynitride layer on the charge trapping layer before forming the tunneling dielectric layer. The tunneling dielectric layer is disposed on the gradient oxynitride layer.

According to some embodiments, the charge trapping layer is made of a nitride. The gradient oxynitride layer is formed on the charge trapping layer through an oxidation process in a process environment containing nitrogen and oxygen. In the gradient oxynitride layer, the closer to the charge trapping layer, the higher the nitrogen content is.

According to some embodiments of the present disclosure, a memory is provided. The memory includes the SONOS structure which is illustrated above and shown in FIG. 2.

The memory may include a non-volatile memory, and the non-volatile memory may include a Read-Only Memory (ROM), a Programmable Read-Only Memory (PROM), an Erasable Programmable Read-Only Memory (EPROM), an Electrically Erasable Programmable Read-Only Memory (EEPROM), a flash memory, and so on.

It should be understood that a term “and/or” only describes an association relationship for describing associated objects and represents that three relationships may exist. For example, A and/or B may represent the following three cases: only A exists, both A and B exist, and only B exists. In addition, the character “/” generally indicates an “or” relationship between the associated objects.

In embodiments of the present disclosure, “a plurality of” indicates two or more.

In embodiments of the present disclosure, descriptions such as “first” and “second” are only used as examples and used to distinguish between objects, but do not indicate a sequence or indicate a specific limitation on a quantity of objects, and cannot constitute any limitation on embodiments of the present disclosure.

Although the present disclosure has been disclosed above, the present disclosure is not limited thereto. Those skilled in the art can modify and vary the embodiments without departing from the spirit and scope of the present disclosure.

Therefore, the protection scope of the present disclosure should be based on the scope defined by the claims.

1. A Silicon Oxide Nitride Oxide Semiconductor (SONOS) structure, comprising:
a semiconductor substrate;
a dielectric layer disposed on the semiconductor substrate;
a charge trapping layer disposed on the dielectric layer;
a tunneling dielectric layer covering the charge trapping layer; and
a conductive layer disposed on the tunneling dielectric layer;
wherein a thickness of the dielectric layer is greater than a thickness of the tunneling dielectric layer.

2. The SONOS structure according to claim 1, further comprising:
a gradient oxynitride layer disposed on the charge trapping layer;
wherein the tunneling dielectric layer is disposed on the gradient oxynitride layer.

3. The SONOS structure according to claim 2, wherein the charge trapping layer is made of a nitride; and
in the gradient oxynitride layer, the closer to the charge trapping layer, the higher a nitrogen content is.

4. The SONOS structure according to claim 2, wherein the tunneling dielectric layer is made of an oxide;
in the gradient oxynitride layer, the closer to the tunneling dielectric layer, the higher an oxygen content is.

5. The SONOS structure according to claim 1, wherein
the dielectric layer is made of an oxide;
the charge trapping layer is made of a nitride;
the tunneling dielectric layer is made of an oxide; and/or
the conductive layer is made of a polycrystalline silicon.

6. A method for erasing the Silicon Oxide Nitride Oxide Semiconductor (SONOS) structure according to claim 1, wherein the SONOS structure further comprises: a source and a drain disposed in the semiconductor substrate; and
the method comprises:
applying a negative erasing voltage to the conductive layer, and grounding the drain.

7. A method for programming the Silicon Oxide Nitride Oxide Semiconductor (SONOS) structure according to claim 1, wherein the SONOS structure further comprises: a source and a drain disposed in the semiconductor substrate; and
the method comprises:
applying a positive programming voltage to the conductive layer, and applying a positive programming voltage to the drain or grounding the drain;
wherein the positive programming voltage applied to the conductive layer is greater than the positive programming voltage applied to the drain.

8. The method according to claim 7, further comprising:
when programming “1”, the positive programming voltage being applied to the drain; and/or
when programming “0”, the drain being grounded.

9-13. (canceled)

14. The method according to claim 6, wherein the SONOS structure further comprises:
a gradient oxynitride layer disposed on the charge trapping layer;
wherein the tunneling dielectric layer is disposed on the gradient oxynitride layer.

15. The method according to claim 14, wherein the charge trapping layer is made of a nitride; and
in the gradient oxynitride layer, the closer to the charge trapping layer, the higher a nitrogen content is.

16. The method according to claim 14, wherein the tunneling dielectric layer is made of an oxide;
in the gradient oxynitride layer, the closer to the tunneling dielectric layer, the higher an oxygen content is.

17. The method according to claim 6, wherein
the dielectric layer is made of an oxide;
the charge trapping layer is made of a nitride;
the tunneling dielectric layer is made of an oxide; and/or
the conductive layer is made of a polycrystalline silicon.

18. The method according to claim 7, wherein the SONOS structure further comprises:
a gradient oxynitride layer disposed on the charge trapping layer;
wherein the tunneling dielectric layer is disposed on the gradient oxynitride layer.

19. The method according to claim 18, wherein the charge trapping layer is made of a nitride; and
in the gradient oxynitride layer, the closer to the charge trapping layer, the higher a nitrogen content is.

20. The method according to claim 18, wherein the tunneling dielectric layer is made of an oxide;
in the gradient oxynitride layer, the closer to the tunneling dielectric layer, the higher an oxygen content is.

21. The method according to claim 7, wherein
the dielectric layer is made of an oxide;
the charge trapping layer is made of a nitride;
the tunneling dielectric layer is made of an oxide; and/or
the conductive layer is made of a polycrystalline silicon.

22. The method according to claim 18, further comprising:
when programming “1”, the positive programming voltage being applied to the drain; and/or
when programming “0”, the drain being grounded.

23. The method according to claim 19, further comprising:
when programming “1”, the positive programming voltage being applied to the drain; and/or
when programming “0”, the drain being grounded.

24. The method according to claim 20, further comprising:
when programming “1”, the positive programming voltage being applied to the drain; and/or
when programming “0”, the drain being grounded.

25. The method according to claim 21, further comprising:
when programming “1”, the positive programming voltage being applied to the drain; and/or
when programming “0”, the drain being grounded.
